(19) United States
(12) Patent Application Publication
(10) Pub. No.: US 2002/0072197 A1
(43) Pub. Date: Jun. 13, 2002

(54) Method for self-aligned shallow trench isolation and method of manufacturing non-volatile memory device using the same

(75) Inventors: Man-Sug Kang, Yongin-city (KR); Byoung-Moon Yoon, Yongin-city (KR); Hee-Seok Kim, Yongin-city (TR); U-In Chung, Yongin-city (KR)

Correspondence Address: Frank Chau, F. CHAU & ASSOCIATES, LLP, Suite 501, 1900 Hempstead Turnpike, East Meadow, NY, 11554, US

(73) Assignee: Samsung Electronics Co., Ltd.

(21) Appl. No.: 09/874,087

(22) Filed: Jun. 5, 2001

(30) Foreign Application Priority Data
Jul. 25, 2000 (KR) 2000-42695

(51) Int. Cl. H01L 21/76

(52) U.S. Cl. 438/424

(57) ABSTRACT

A method of self-aligned shallow trench isolation and a method of manufacturing a non-volatile memory using the same are disclosed. An oxide layer, a first silicon layer and a nitride layer are successively formed on a semiconductor substrate. By using a single mask, the nitride layer, first silicon layer and oxide layer are etched to form an oxide layer pattern, a first silicon layer pattern and a nitride layer pattern. Subsequently, the upper portion of the substrate adjacent to the first silicon layer pattern is etched to a trench. The first silicon layer pattern and substrate are selectively etched to protrude the oxide layer pattern. The inner surface of the trench is oxidized to form a trench thermal oxide layer. Finally, a field oxide layer that fills up the trench is formed. Since the present invention prevents the sidewalls of the first silicon layer pattern from having a positive slope, a silicon residue does not remain during a subsequent gate etching process.

### BACKGROUND OF THE INVENTION

1. Technical Field

The present invention relates to a device isolation method and a method of manufacturing a semiconductor device comprising the same. More particularly, the present invention relates to a self-aligned shallow trench isolation (SA-STI) technique that simultaneously forms a gate and an active region, and a method of manufacturing a non-volatile memory device using the same.

2. Description of the Related Art

One primary goal in the manufacture of semiconductor memory devices is to maximize the number of cells on a single silicon wafer. A memory cell density (i.e., the number of storage bits on a silicon chip) is primarily determined by the layout of cells within a cell array and the physical dimensions of the cells themselves. In addition, a scaling of the chips to smaller dimensions is desirable for enhancing operational speed of the memories. However, under the half-micron ground rule, scalability of the cell layout is limited by the photolithographic resolution attainable during manufacturing of the memory devices and by alignment tolerances of masks used during production. Alignment tolerances are, in turn, limited by the mechanical techniques which are employed to form the masks and the techniques used to register these masks between layers. Since the likelihood of the number of alignment errors is compounded during a multi-stage fabrication, it is preferable to use as few masks as possible to minimize the likelihood of misalignment. Accordingly, “self-alignment” processing steps have been developed to produce semiconductor devices.

To increase the memory cell density, individual cells are isolated using isolation devices, which allow cells to be moved much closer together. One consideration in the design of high density semiconductor devices is the size of the isolation structures, since isolation structures between individual cells within the memory cell array consume regions of the chip that are otherwise needed for active circuitry. Thus, to increase the density of a memory cell array within a substrate, it is desirable to minimize the size of these isolation structures. However, the size of the isolation structures is generally dictated by its process of formation and/or alignment. Typically, an isolation structure is grown at various regions of the chip by a thermal field oxidation process, such as a LOCal Oxidation of Silicon (hereinafter referred to as “LOCOS”). According to the LOCOS method, after a pad oxide layer and a nitride layer are successively formed, the nitride layer is subjected to patterning. Then, the patterned nitride layer is used as a mask to selectively oxidize a silicon substrate to form field oxide regions. However, a problem associated with the method of LOCOS isolation is a bird's beak effect where a growth of oxide in the form of a bird's beak encroaches upon a side plane of the pad oxide layer beneath the nitride layer. Due to the bird's beak formed at the end portion of the field oxide layer, the field oxide layer is extended into an active region of the memory cell, thereby decreasing the width of the active region. This phenomenon is undesirable because it degrades the electrical characteristics of the memory device.

For this reason, a shallow trench isolation (hereinafter referred to as “STI”) structure is preferred in the construction of ultra-high scale semiconductor devices. In the STI process, a silicon substrate is first etched to form a trench, and then an oxide layer is deposited to fill up the trench. Thereafter, the oxide layer is etched via an etch back or a chemical mechanical polishing (CMP) method so as to form a field oxide layer inside the trench.

The foregoing LOCOS and STI methods commonly include a mask step that defines the regions of the isolation structure on the substrate and a step that forms the field oxide layer within those regions. After forming the isolation structure, steps for forming the memory cells are carried out. As such, alignment errors associated both with forming the isolation structure and forming the memory cells are compounded to increase the chances of mis-alignment, which in turn may result in failure of the device.

One method of reducing misalignment when constructing a floating gate of a non-volatile memory device includes, for example, forming an STI structure using a self-aligned floating gate, such as by the process disclosed in U.S. Pat. No. 6,013,551 to Jong Chen, et al. According to the method described therein, a floating gate and an active region thereof are simultaneously defined and fabricated using a single mask so that alignment errors are not compounded.

Advantageously, non-volatile memory devices have long-term, i.e., almost indefinite, storage capacity. In recent years, demand for such electrically erasable programmable read-only memory devices (EEPROMS) or flash EEPROMS has increased. Memory cells of these devices generally have a vertically stacked gate structure comprising a floating gate formed on a silicon substrate with a tunnel oxide layer interposed therebetween, and a control gate formed over and/or around the floating gate with a dielectric (or insulating) interlayer interposed therebetween. In a flash memory cell having this structure, data is stored by transferring electrons to and from the floating gate by applying a controlled voltage to the control gate and the substrate. The dielectric interlayer functions to maintain the potential on the floating gate.

FIGS. 1A to 1E are exemplary cross-sectional views illustrating a conventional method of manufacturing a flash memory device using a self-aligned STI technique.

Referring to FIG. 1A, after forming an oxide layer 11 on a silicon substrate 10, a first polysilicon layer 13 and a nitride layer 15 are preferably successively formed on the oxide layer 11. The oxide layer 11 serves as a tunnel oxide layer (i.e., a gate oxide layer) of the flash memory cell. The first polysilicon layer 13 serves as a floating gate. The nitride layer 15 serves as a polish-stopping layer during a subsequent chemical mechanical polishing (CMP) process.

Referring to FIG. 1B, a photolithography process using one mask is performed to pattern the nitride layer 15, the first polysilicon layer 13, and the oxide layer 11 to form a nitride layer pattern 16, a first polysilicon layer pattern 14, and an oxide layer pattern 12. Thereafter, by using the above mask, exposed portions of the substrate 10 are etched to a predetermined depth to form a trench 18. That is, the active regions and floating gates are simultaneously defined during the trench forming process using the single mask.

Referring to FIG. 1C, exposed portions of the trench 18 are subjected to thermal treatment in an oxygen atmosphere for curing silicon damage caused by high-energy ion bombardment during the trench etching process. Subsequently, a trench thermal oxide layer 20 is formed along the inner surface including the bottom plane and sidewall of the trench 18 by the oxidation reaction of the exposed silicon with an oxidant.

During the above oxidation process, the oxidant encroaches upon the side of oxide layer pattern 12 at the lower portion of first polysilicon layer pattern 14 to form a bird's beak (a) as shown in FIG. 2. Further, since the oxidation progresses only on the surfaces of the silicon substrate 10 and the first polysilicon layer pattern 14, a volume expansion due to the oxidation is limited to the edges of the interface between the first polysilicon layer pattern 14 and the oxide layer pattern 12 and to the interface between the oxide layer pattern 12 and the silicon substrate 10. Thus, the diffusion of oxygen progresses slowly to suppress the oxidation, since the stress due to the volume expansion is concentrated on these interfaces (refer to “b” in FIG. 2).

As a result, because a bottom edge portion of the first polysilicon layer pattern 14 is bent outward, the sidewall of the first polysilicon layer pattern 14 has a positive slope (refer to “c” in FIG. 2). Here, the positive slope indicates the occurrence of sidewall erosion with respect to the etchant. In other words, as shown in the drawing, the intrusion of the oxidant into the portion underlying the nitride layer pattern 16 is blocked by the existence of the nitride layer pattern 16 to provide a negative slope at the upper portion of the sidewall of the first polysilicon layer pattern 14. Meanwhile, the bottom edge portion of the lower portion of the first polysilicon layer pattern 14 is bent outward to have a positive slope, which is eroded by an etchant introduced from above the substrate in the same manner as in the sidewall of a mesa structure or to act as a buffer for the underlying layer when the etchant is applied.

Referring to FIG. 1C and FIG. 1D, after forming an oxide layer via a chemical vapor deposition (hereinafter referred to as “CVD”) method for filling up the trenches 18, the CVD-oxide layer is removed via a chemical mechanical planarization (CMP) process until the upper surface of the nitride layer pattern 16 is exposed. As a result, a field oxide layer 22 is formed inside the trenches 18.

After removing the nitride layer pattern 16 preferably via a phosphoric acid stripping process, a second polysilicon layer for the floating gate is deposited on the first polysilicon layer pattern 14 and the field oxide layer 22. The second polysilicon layer makes contact with the first polysilicon layer pattern 14, and functions to increase the area of the dielectric interlayer that is formed in a subsequent process.

Thereafter, the second polysilicon layer over field oxide layer 22 is partially etched via a photolithography process to form a second polysilicon layer pattern 24. Subsequently, an ONO dielectric interlayer 26 and a control gate 28 are preferably successively formed on the entire surface of the resultant structure. The control gate 28 is preferably formed by a polycide structure obtained by stacking a tungsten silicide layer on a doped polysilicon layer.

In FIG. 1 E, the control gate 28 is patterned via a photolithography process. The exposed dielectric interlayer 26 and the second and first polysilicon layer patterns 24 and 14 are then preferably sequentially anisotropically etched via a dry etch process. As a result, the stacked gate structure comprising the floating gate 25 (which comprises the first and second polysilicon layer patterns 14 and 24) and the control gate 28, is formed on the memory cell region.

As shown by “A” in FIG. 1D, a lower portion of the sidewall of the first polysilicon layer pattern 14 has a positive slope. Therefore, due to the characteristics of the anisotropic etching (i.e., where etching is performed mainly in the vertical direction) of the dry etch process, the bottom edge portion of the first polysilicon layer pattern 14 masked by the field oxide layer 22 is not etched and thus remains intact. As a result, a line-shaped polysilicon residue 14a is formed along the surface boundary of the active region and the field oxide layer 22. This polysilicon residue 14a forms an electrical connection between adjacent floating gates, causing an electrical short and failure of the device.

Accordingly, a need exists for a self-aligned shallow trench isolation method for preventing electrical failure of a semiconductor memory device. Moreover, a need exists for a method of manufacturing a non-volatile memory device that avoids a positive slope of the sidewalls of a floating gate.

### SUMMARY OF THE INVENTION

According to an aspect of the present invention, a self-aligned shallow trench isolation method is provided comprising the steps of forming an oxide layer on a semiconductor substrate; forming a first silicon layer on the oxide layer; forming a nitride layer on the first silicon layer; etching the nitride layer, the first silicon layer and the oxide layer using a single mask to thereby form an oxide layer pattern, a first silicon layer pattern and a nitride layer pattern; etching an upper portion of the substrate adjacent to the first silicon layer pattern using the mask to thereby form a trench; selectively etching the first silicon layer pattern and the substrate to protrude the oxide layer pattern as compared with the first silicon layer pattern and the substrate, oxidizing an inner surface portion of the trench to form a trench thermal oxide layer on an inner surface of the trench, and forming a field oxide layer for filling up the trench.

According to another aspect of the present invention, a method of manufacturing a non-volatile memory device is provided comprising the steps of forming an oxide layer for use as a gate oxide layer on a semiconductor substrate; forming a first silicon layer for a floating gate on the oxide layer; forming a nitride layer on the first silicon layer; etching the nitride layer, the first silicon layer and the oxide layer using a single mask to thereby form an oxide layer pattern, a first silicon layer pattern and a nitride pattern; etching the upper portion of the substrate adjacent to the first silicon layer using the mask to thereby form a trench aligned with the first silicon layer pattern for defining an active region of the substrate; selectively etching the first silicon layer pattern and the substrate to protrude the oxide layer pattern as compared with the first silicon layer pattern and the substrate; oxidizing an inner surface portion of the trench to form a trench thermal oxide layer on an inner surface of the trench; forming a field oxide layer for filling up the trench; and successively forming a dielectric interlayer and a control gate on the first silicon layer pattern.

According to yet another aspect of the present invention, a method of manufacturing a non-volatile memory device is provided comprising the steps of forming an oxide layer for use as a gate oxide layer on a semiconductor substrate; forming a first silicon layer for a floating gate on the oxide layer; forming a nitride layer on the first silicon layer; etching the nitride layer, the first silicon layer and the oxide layer using a single mask to thereby form an oxide layer pattern, a first silicon layer pattern and a nitride layer pattern; etching the upper portion of the substrate adjacent to the first silicon layer pattern using the mask to thereby form a trench aligned with the first silicon layer pattern for defining an active region of the substrate; selectively etching the oxide layer pattern to protrude the first silicon layer pattern and the substrate as compared with the oxide layer pattern; rounding a bottom edge portion of the first silicon layer pattern and an upper edge portion of the substrate; oxidizing an inner surface portion of the trench to form a trench thermal oxide layer on an inner surface of the trench; forming a field oxide layer for filling up the trench; and successively forming a dielectric interlayer and a control gate on the first silicon layer pattern.

According to yet another aspect of the present invention, a method for manufacturing a non-volatile memory device is provided comprising the steps of forming an oxide layer for use as a gate oxide layer on a semiconductor substrate; forming a Ge-doped silicon layer for use as a floating gate on the oxide layer; forming a first silicon layer for use as a floating gate on the Ge-doped silicon layer; forming a nitride layer on the first silicon layer; etching the nitride layer, the first silicon layer, the Ge-doped silicon layer and the oxide layer using a single mask to thereby form an oxide layer pattern, a Ge-doped silicon layer pattern, a first silicon layer pattern and a nitride layer pattern, and simultaneously, to form an undercut in the Ge-doped silicon layer pattern; etching the upper portion of the substrate adjacent to the first silicon layer pattern using the mask to thereby form a trench aligned with the first silicon layer pattern for defining an active region of the substrate; oxidizing an inner surface portion of the trench to form a trench thermal oxide layer on an inner surface of the trench; forming a field oxide layer for filling up the trench; and successively forming a dielectric interlayer and a control gate on the first silicon layer pattern.

Specifically, according to a first embodiment of the present invention, the first silicon layer pattern aligned to the trench and the substrate are selectively etched to protrude the oxide layer pattern, and then the inner surface portion of the trench is oxidized. At the edge portion of the interface between the first silicon layer pattern and oxide layer pattern, the volume expansion due to oxidation progresses laterally along the surface of the protrusive oxide layer. Thus, a positive slope of the sidewall of the first silicon layer can be avoided.

According to a second embodiment of the present invention, the oxide layer pattern is selectively etched to protrude the first silicon layer pattern and substrate, and then the first silicon layer pattern and substrate are selectively etched. By doing so, the bottom edge portion of the first silicon layer pattern and the upper edge portion of the substrate, which protrude as compared with the oxide layer pattern, are rounded. If the oxidation of the inner surface portion of the trench is carried out at this state, each sidewall of the first silicon layer pattern has a negative slope. Therefore, since the exposed portions of the first silicon layer pattern are completely removed during a subsequent gate etching, silicon residues do not remain along the surface boundary of the field oxide layer and active region.

According to a third embodiment of the present invention, a Ge-doped silicon layer having higher dry etch rate and wet etch rate than those of a typical silicon layer is inserted between the oxide layer and first silicon layer. By doing so, each sidewall of a silicon stack comprising the first silicon layer pattern and Ge-doped silicon layer pattern, has a negative slope. Further, since the oxide layer pattern protrudes without an additional etching process, the sidewalls of the silicon stack maintain the negative slope after the inner surface portion of the trench is oxidized.

These and other aspects, features, and advantages of the present invention will be described or become apparent from the following detailed description of preferred embodiments, which is to be read in connection with the accompanying drawings.

### BRIEF DESCRIPTION OF THE DRAWINGS

FIG. 1A to 1E illustrate a prior art method of manufacturing a flash memory device using a self-aligned shallow trench isolation process;

FIG. 2 is an enlarged exemplary cross-sectional view showing portion X of FIG. 1C;

FIG. 3A to FIG. 31 are exemplary cross-sectional views illustrating a method of manufacturing a flash memory device using a self-aligned shallow trench isolation process according to a first embodiment of the present invention;

FIGS. 4A to FIG. 4E are exemplary cross-sectional views illustrating a method of manufacturing a flash memory device using a self-aligned shallow trench isolation process according to a second embodiment of the present invention; and

FIGS. 5A to 5G are exemplary cross-sectional views illustrating a method of manufacturing a flash memory device using a self-aligned shallow trench isolation process according to a third embodiment of the present invention.

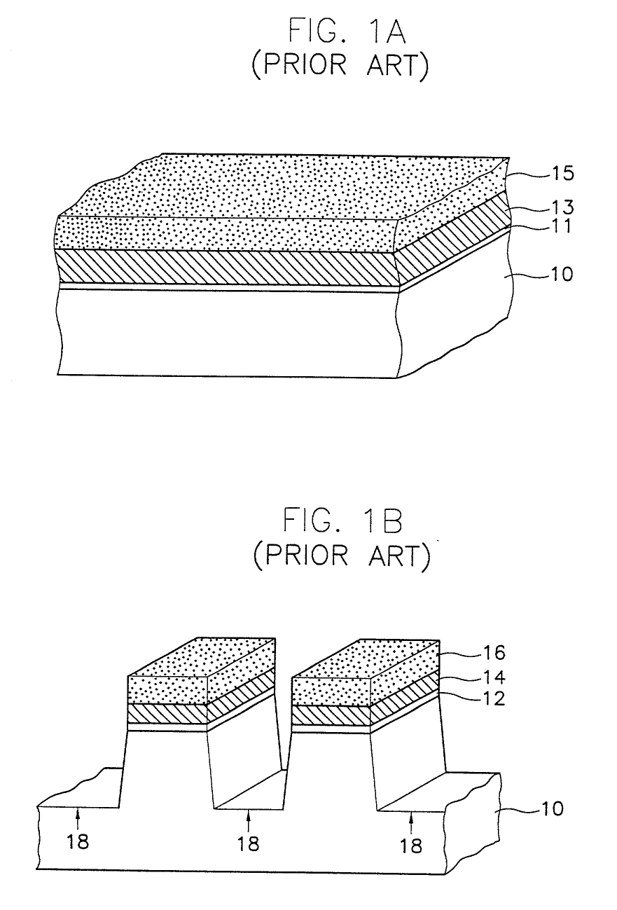

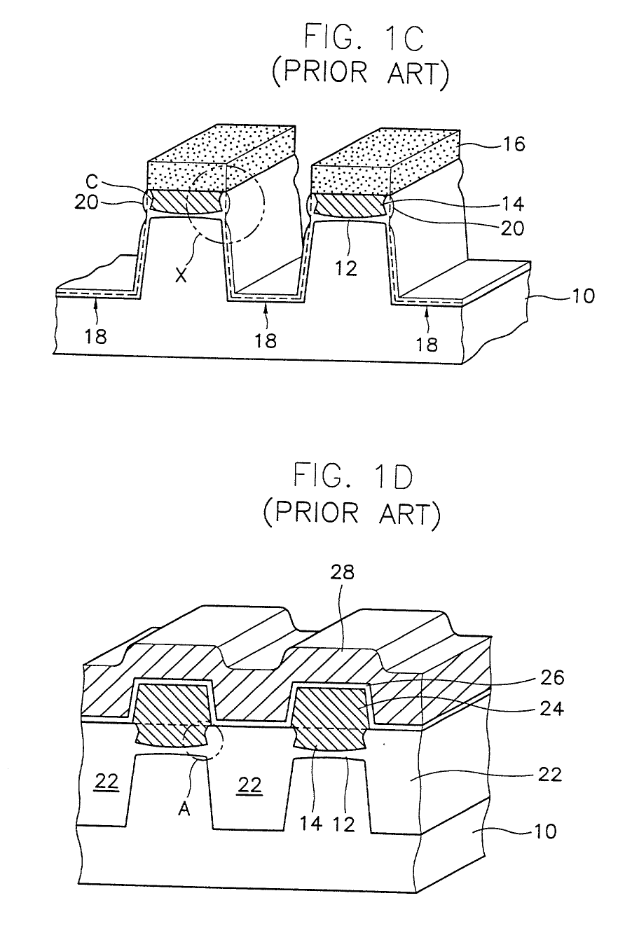

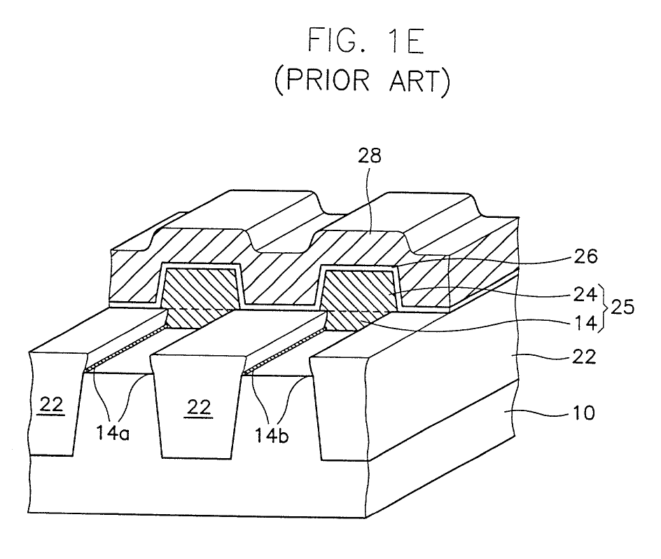

### DETAILED DESCRIPTION OF PREFERRED EMBODIMENTS

Hereinafter, the preferred embodiments of the present invention are described with reference to the accompanying drawings. It is to be noted that when a layer, structure, or pattern is described herein as being on, lying over, or covering another layer, pattern, or structure, it is meant that an interceding layer, pattern, or structure may or may not be included.

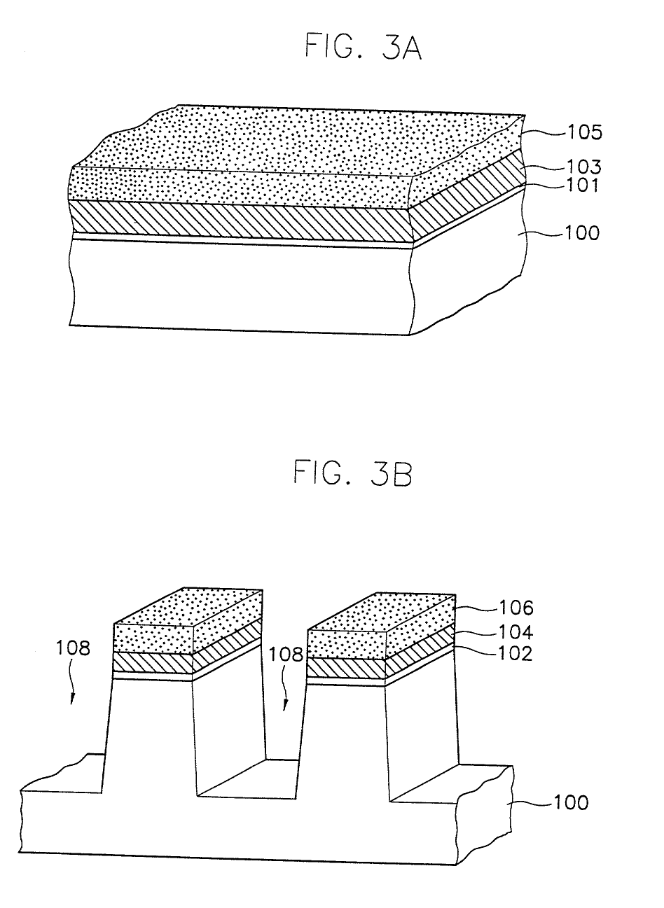

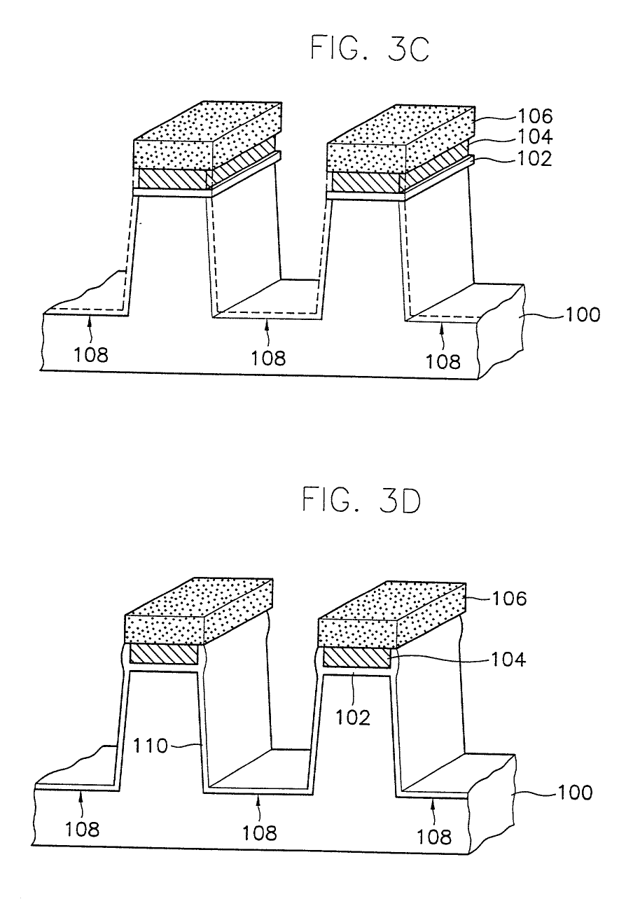

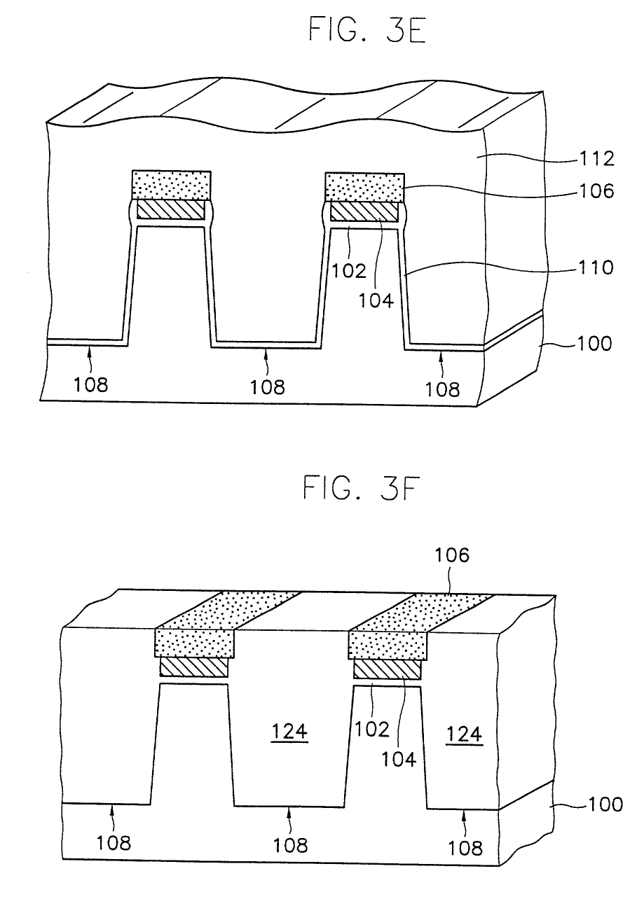

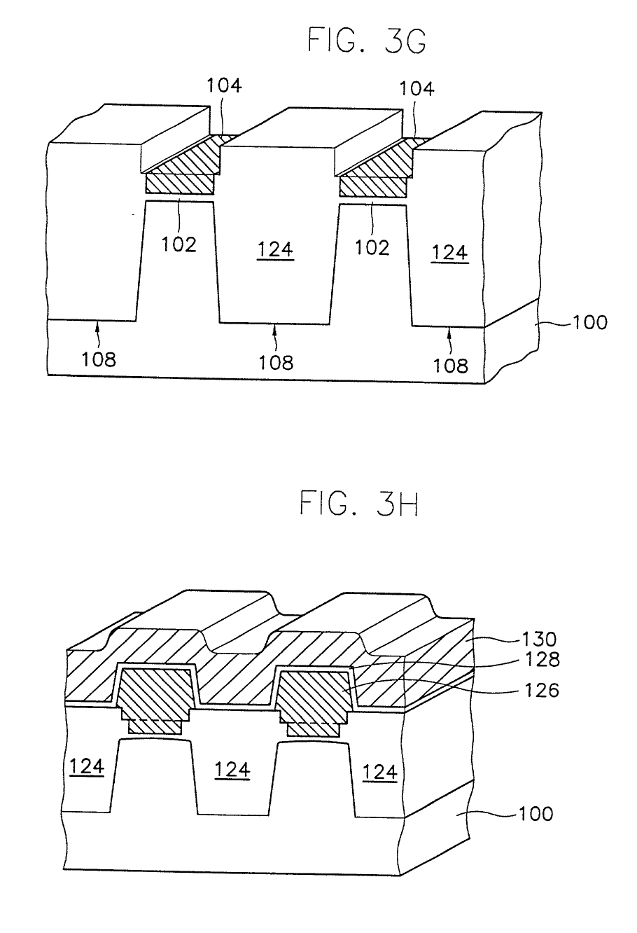

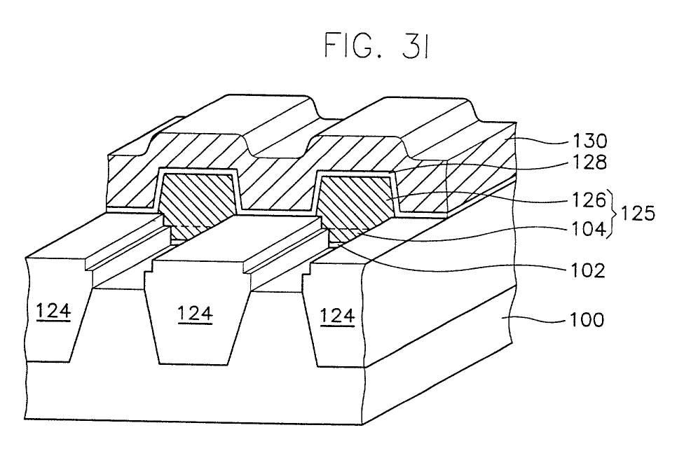

FIGS. 3A to 3I are exemplary cross-sectional views illustrating a method of manufacturing a non-volatile memory device using the self-aligned shallow trench isolation process according to a first embodiment of the present invention.

Referring to FIG. 3A, a silicon oxide layer or silicon oxynitride layer with a thickness of about 100 Å is grown on a semiconductor substrate 100 to form an oxide layer 101 which is to be used as a gate oxide layer (e.g., a tunnel oxide layer) of a cell transistor. The substrate 100 may comprise, for example, a material such as silicon. A first silicon layer 103 which is to be used a floating gate, is deposited on the oxide layer 101 to a depth of about 300 Å to about 1000 Å, via a LPCVD method. Then, the first silicon layer 103 is doped with a high-concentration of N-type impurities via a typical doping method, for example, POCl₃ diffusion, ion implantation or in-situ doping, etc. Preferably, the first silicon layer pattern 103 is comprised of a polysilicon or an amorphous silicon.

Subsequently, a nitride layer 105 is deposited on the first silicon layer 103 to a thickness of about 1000 Å to about 2000 Å, via a LPCVD method. The nitride layer 105 serves as a polish-stopping layer during a subsequent chemical mechanical planarization (CMP) process.

Referring to FIG. 3B, the nitride layer 105, the first silicon layer 103 and the oxide layer 101 of FIG. 3A are dry etched to form an oxide layer pattern 102, a first silicon layer pattern 104 and a nitride layer pattern 106 via a photolithography process having one mask for defining a floating gate. Next, by using the above mask, the upper portion of the substrate 100 adjacent to the first silicon layer pattern 104 is etched away to a depth of about 2000 Å to about 5000 Å, thereby forming trenches 108.

As a result, the first silicon layer patterns 104 are separated from one another by the trench 108. By forming the trench 108, an active region and the floating gate are simultaneously defined using a single mask. Accordingly, the floating gate is self-aligned with the active region.

Referring to FIG. 3C, by using a chemical having a high selectivity to an oxide film, the first silicon layer pattern 104 and the substrate 100 are selectively isotropically etched so that the oxide layer pattern 102 protrudes from the first silicon layer pattern 104 and the substrate 100. Preferably, the quantity of the first silicon layer pattern 104 and the substrate 100 that is selectively etched is more than about 50%, but preferably at about 60%, of the thickness of a trench thermal oxide layer to be formed in a subsequent process. According to the present embodiment, the quantity that is selectively etched of the first silicon layer pattern 104 and the substrate 100 is more than about 30 Å.

Preferably, the selective etching of the first silicon layer pattern 104 and the substrate 100 is carried out via a wet etch method. Alternatively, a dry etch method having an isotropic etching characteristic may be used. Further, an isotropic etch process may be carried out by mixing a wet etching method and a dry etching method.

Referring to FIG. 3D, the inner surface portion of the trench 108 is treated in an oxidation atmosphere to eliminate silicon damage caused by high-energy ion impact during the trench etching process, and also to prevent current leakage. Subsequently, a trench thermal oxide layer 110 is formed along the inner surface of the trench 108, i.e., the bottom surface and sidewalls thereof, to a thickness of about 20 Å to about 500 Å. Preferably, in order to minimize the stress during the formation of the oxide layer, the trench thermal oxide layer 110 is formed at a temperature of more than about 700° C. via a wet oxidation method.

As widely known in the art, a reaction for forming an oxide layer is written as follows:

Si+O₂+H₂O→SiO₂

As noted from the above reaction, since the diffusion of oxygen into the layer having the silicon (Si) source results in the oxidation of silicon, the oxidation reaction occurs on the surface of the first silicon layer pattern 104 and the surface of the silicon substrate 100. Further, the oxidation reaction occurs at an interface between the first silicon layer pattern 104 and the oxide layer pattern 102, and at an interface between the oxide layer pattern 102 and the silicon substrate 100.

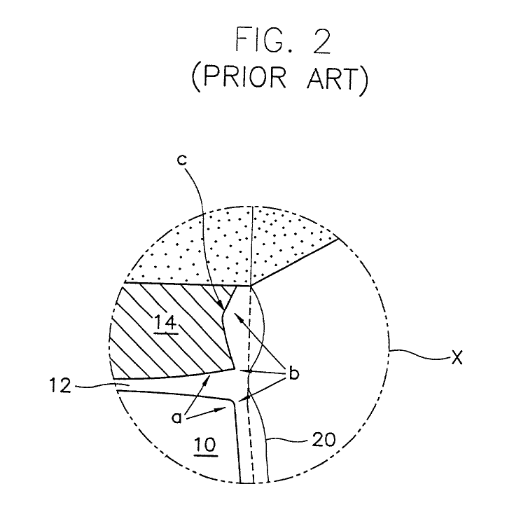

According to the conventional method where a first silicon layer pattern and an oxide layer pattern have the same interface plane, at an edge portion of the interface between the first silicon layer pattern and the oxide layer pattern, the volume expansion due to the oxidation progresses vertically along the sidewall of the first silicon layer pattern having the silicon (Si) source. Thus, the bottom edge portion of the first silicon layer pattern is bent outward as shown in FIG. 2, so that the sidewall thereof has a positive slope, as discussed above.

On the contrary, according to an aspect of the present invention, the oxide layer pattern 102 protrudes as compared with the first silicon layer pattern 104 and the substrate 100. Thus, at an edge portion of the interface between the first silicon layer pattern 104 and the oxide layer pattern 102, the volume expansion due to oxidation progresses along a lateral surface of the protruding oxide layer pattern 102, thereby preventing the bottom edge portion of the first silicon layer pattern 104 from having a positive slope.

Referring to FIG. 3E, an oxide layer 112 with good gap-filling characteristics, for example, undoped silicate glass (USG), tetra-ethyl ortho-silicate undoped silicate glass (O₃-TEOS USG), or a high-density plasma (HDP) oxide layer, is deposited via a chemical vapor deposition (CVD) method to a thickness of about 5000 Å to fill the trench 108. Preferably, the high-density plasma (HDP) oxide layer is formed using SiH₄, O₂ and Ar gases as a plasma source.

Referring to FIG. 3F, the CVD-oxide layer 112 of FIG. 3E is planarized via an etch-back or a CMP process until the upper surface of the nitride layer pattern 106 is exposed. Thus, the CVD-oxide layer 112 on the nitride layer pattern 106 is removed to thereby form a field oxide layer 124 inside the trench 108.

Referring to FIG. 3G, the nitride layer pattern 106 of FIG. 3E is removed via a stripping process using phosphoric acid to expose the first silicon layer pattern 104. Then, a pre-cleaning step is performed to clean the substrate preferably for about 30 seconds using an etchant including fluoride acid. The field oxide layer 124 is partially removed by stripping the nitride layer pattern 106 and by the pre-cleaning process. At this time, the thickness of the field oxide layer 124 is reduced by over about 250 Å.

Referring to FIG. 3H, a second silicon layer comprising a polysilicon layer or an amorphous silicon layer is deposited on the first silicon layer pattern 104 and the field oxide layer 124 via a LPCVD method to a thickness of over about 3000 Å. Subsequently, the second silicon layer is doped with a high concentration of N-type impurities via a typical doping method, for example, POCl₃ diffusion, ion implantation or in-situ doping. The second silicon layer as deposited thus lies in electrical contact with the first silicon layer pattern 104. The second silicon layer is formed to increase the area of a dielectric interlayer formed in a subsequent process, which is preferably formed as thick as possible.

Subsequently, the second silicon layer on the field oxide layer 124 is partially removed via a photolithography process to form a second silicon layer pattern 126. As a result, the floating gates of each cell are separated from those of the neighboring cells.

Successively, an oxide-nitride-oxide (ONO) dielectric interlayer 128 is formed on the entire surface of the resultant structure. The ONO dielectric layer 128 may be formed, for example, in the following way: after the second silicon layer pattern 126 is oxidized to grow a first oxide layer to a thickness of about 100 Å, a nitride layer is deposited thereon to a thickness of about 130 Å and a second oxide layer to a thickness of about 40 Å is deposited on the nitride layer.

Subsequently, a control gate 130 which is preferably obtained by stacking an N⁺ type-doped polysilicon layer and a metal silicide layer such as tungsten silicide WSix, titanium silicide TiSix, cobalt silicide CoSix, and tantalum silicide TaSix, is formed on the dielectric interlayer 128. Preferably, the polysilicon layer of the control gate 130 is formed to a thickness of about 1000 Å and the metal silicide layer thereof is formed to a thickness of about 1000 Å to about 1500 Å.

Referring to FIG. 31, after patterning the control gate 130 via a photolithography process, the exposed dielectric interlayer 128, the second silicon layer pattern 126 and the first silicon layer pattern 104 are successively patterned in each cell unit via a dry etch method. As a result, a stacked gate comprising the floating gate 125 (the floating gate being comprised of the first and second silicon layer patterns 104 and 126 respectively), and the control gate 130 is formed on the memory cell region.

Advantageously, because the sidewall of the first silicon layer pattern 104 has no positive slope, the exposed portions of the first silicon layer pattern 104 are completely removed during the above-described dry etch process. Therefore, a silicon residue does not remain at the surface boundary of the field oxide layer 124 and the active region.

According to the first embodiment of the present invention described above, the first silicon layer pattern 104 aligned to the trench 108 and the substrate 100 are selectively (and partially) etched to protrude the oxide layer pattern 102, and the inner surface portion of the trench 108 is then oxidized. Since the volume expansion due to oxidation progresses laterally along the surface of the protruding oxide layer pattern 102 (instead of vertically along the sidewall of the first silicon layer pattern), the undesirable positive slope of the sidewall of the first silicon layer pattern 104 can be avoided.

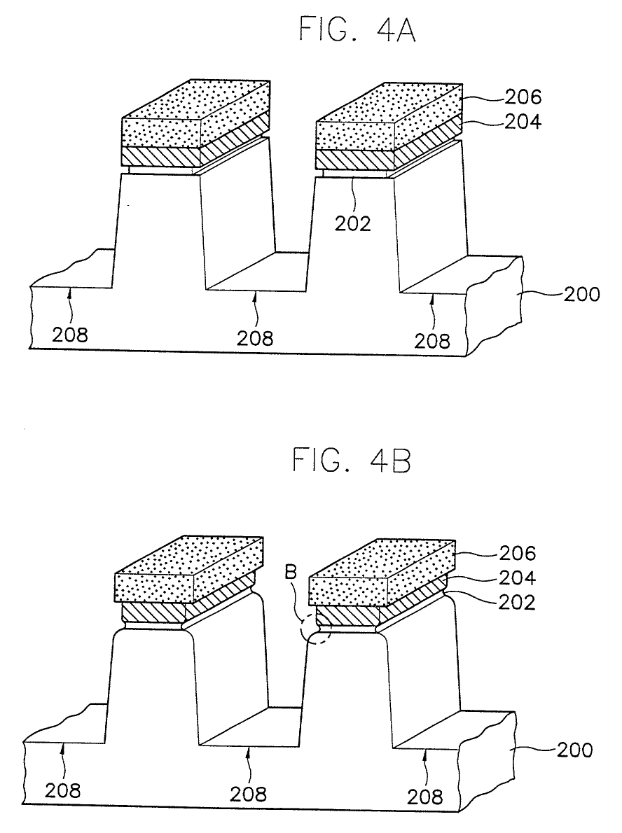

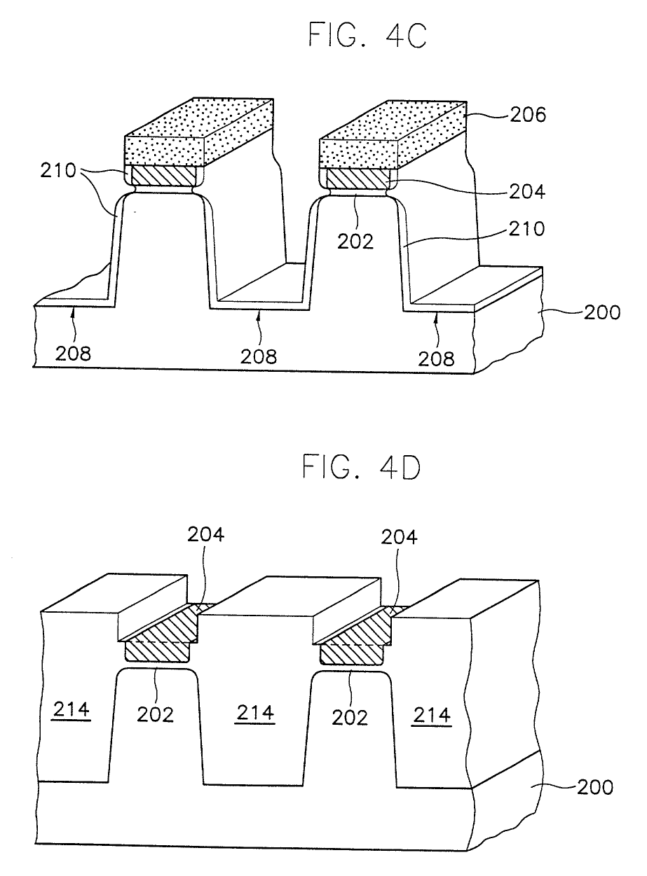

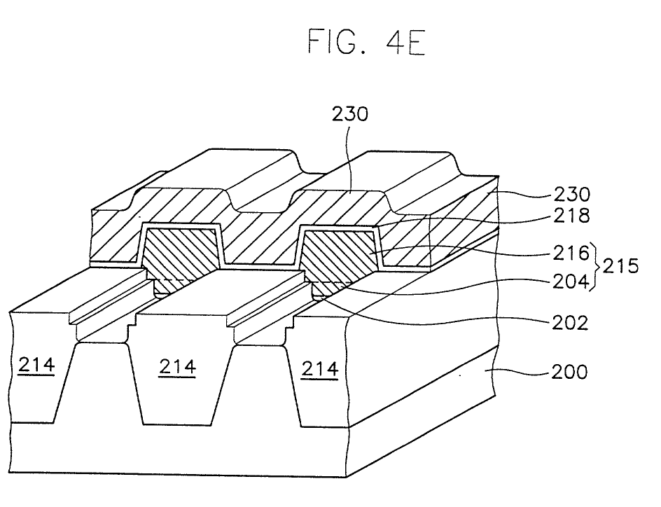

FIGS. 4A to 4E are perspective views illustrating a method of manufacturing a non-volatile memory device using the self-aligned shallow trench isolation process according to a second embodiment of the present invention.

Referring to FIG. 4A, an oxide layer for use as a gate oxide layer, a first silicon layer for use as a floating gate, and a nitride layer for use as a polish-stopping layer are successively deposited on a semiconductor substrate 200, preferably via the same method as the above-described first embodiment of the present invention.

Subsequently, the nitride layer, the first silicon layer and the oxide layer are dry etched to form an oxide layer pattern 202, a first silicon layer pattern 204 and a nitride layer pattern 206 via a photolithography process having one mask for defining a floating gate. Next, by using the above mask, an upper portion of the substrate 200 adjacent to the first silicon layer pattern 204 is etched away to a depth of about 2000 Å to about 5000 Å, thereby forming trenches 208. As a result, the first silicon layer patterns 204 are self-aligned with the active regions defined by the trench 208.

Subsequently, by using a chemical having a high selectivity to a silicon layer, a portion of the oxide layer pattern 202 is selectively isotropically etched via a wet etch method, to thereby protrude the first silicon layer pattern 204 and the substrate 200 as compared with the oxide layer pattern 202. Preferably, the quantity of the oxide layer pattern 202 that is selectively etched is more than about 100 Å.

Referring to FIG. 4B, by using a chemical having a high selectivity to an oxide layer, the first silicon layer pattern 204 and the substrate 200 are preferably selectively isotropically etched so that the oxide layer pattern 202 protrudes as compared with the first silicon layer pattern 204 and the substrate 200. At this time, since the first silicon layer pattern 204 and the substrate 200 protrudes as compared with the oxide layer pattern 202, the etching is carried out three-dimensionally at an exposed bottom edge portion of the first silicon layer pattern 204 and the upper edge portion of the substrate 200. As a result, each bottom edge portion of the first silicon layer pattern 204 is caused to be rounded, so that each sidewall thereof has a negative slope as shown in B. Here, the negative slope denotes that an upper plane of a pattern (for example, the first silicon layer pattern) is longer than a lower plane of that pattern.

It is preferable that the amount selectively etched from the first silicon layer pattern 204 and the substrate 200 is over about 40% of a thickness of a trench thermal oxide layer formed in a subsequent process, or is less than the amount selectively etched of the oxide layer pattern 202. According to the present embodiment, the amount selectively etched from the oxide layer pattern 202 is preferably over about 100 Å, while the amount selectively etched from the first silicon layer pattern 204 and the substrate 200 is preferably below about 100 Å.

Preferably, the selective etching of the first silicon layer pattern 204 and the substrate 200 is carried out via a wet etch method. Alternatively, a dry etch method having an isotropic etching characteristic may be used. Further, an isotropic etch process may be carried out by mixing a wet etching method and a dry etching method.

Alternatively, an annealing process using hydrogen (H₂) gas may be performed to round the bottom edge portion of the first silicon layer pattern 204. When H₂ annealing is carried out after selectively etching the oxide layer pattern 202 as shown in FIG. 4A, the bottom edge of the first silicon layer pattern 204 and the active edge of the substrate 200 are rounded so that each sidewall of the first silicon layer pattern has a negative slope. At this time, the H₂ annealing process is performed at a temperature of about 750° C. to about 950° C., preferably about 825° C., under a pressure of about 10 torr and a flow rate of about 1 SLM (standard liter per minute). Preferably, the H₂ annealing process is used in lieu of the etching process described above.

Referring to FIG. 4C, an inner surface portion of the trench 208 is treated in an oxidation atmosphere to form a trench oxide layer 210 having a thickness of about 20 Å to about 500 Å. Preferably, to minimize the stress during the formation of the oxide layer, the trench thermal oxide layer 210 is formed at a temperature of more than 700° C., via a wet oxidation method.

According to the present embodiment, each sidewall of the first silicon layer pattern 204 has a negative slope prior to the formation of the trench thermal oxide layer 210. Thus, during the oxidation process, although the stress due to the volume expansion is concentrated on the edge portions of the interface between the first silicon layer pattern 204 and the oxide layer pattern 202 so that the bottom edge portion of the first silicon layer pattern 204 is caused to have a small positive slope, each sidewall of first silicon layer pattern 204 ultimately has a negative slope. For example, if the trench-sidewall oxidation is carried out after selectively etching the first silicon layer pattern 204 to form the sidewalls thereof having a negative slope of about 45 degrees, the bottom edge portion of the first silicon layer pattern 204 may be caused to have a positive slope of about 20 degrees. However, each sidewall of the first silicon layer pattern 204 that is finally obtained has a negative slope of about 20 to 25 degrees.

Referring to FIG. 4D, an oxide layer with good gap-filling characteristics, for example, undoped silicate glass (USG), tetra-ethyl ortho-silicate undoped silicate glass (O₃-TEOS USG), or a high density plasma (HDP) oxide layer, is deposited via a CVD method to a thickness of about 5000 Å in order to fill the trenches 208. Then, the CVD-oxide layer is planarized via an etch-back or CMP process until an upper surface of the nitride layer pattern 206 is exposed, thereby forming a field oxide layer 214 inside the trenches 208.

Thereafter, the nitride layer pattern 206 of FIG. 4C is removed via a stripping process using phosphoric acid to expose the first silicon layer pattern 204, and then a pre-cleaning step is performed to clean the substrate by using an etchant including fluoride acid.

Referring to FIG. 4E, a second silicon layer for the floating gate is deposited on the first silicon layer pattern 204 and the field oxide layer 214 via a LPCVD method to a thickness of over about 3000 Å. Subsequently, the second silicon layer is doped with a high concentration of N-type impurities via a typical doping method, for example, POCl₃ diffusion, ion implantation or in-situ doping. Then, the second silicon layer on the field oxide layer 214 is partially removed via a photolithography process to form a second silicon layer pattern 216.

Next, after forming an ONO dielectric interlayer 218 on the entire surface of the resultant structure, a control gate 230 which is obtained by stacking an N⁺ type-doped polysilicon layer and a metal silicide layer such as tungsten silicide (WSix), titanium silicide (TiSix), cobalt silicide (CoSix), and tantalum silicide (TaSix), is formed on the dielectric interlayer 218. Preferably, the polysilicon layer of the control gate 230 is formed to a thickness of about 1000 Å and the metal silicide layer thereof is formed to a thickness of about 1000 Å to about 1500 Å.

After patterning the control gate 230 via the photolithography process, the exposed dielectric interlayer 218, the second silicon layer pattern 216 and the first silicon layer pattern 204 are preferably successively patterned in each cell unit via a dry etch method. As a result, a stacked gate comprising the floating gate 215 (which is comprised of the first and second silicon layer patterns 204 and 216), and the control gate 230 is formed on the memory cell region.

Because each sidewall of the first silicon layer pattern 204 has a negative slope, the exposed portions of the first silicon layer pattern 204 are completely removed during the above-described dry etch process. Therefore, silicon residue does not remain at the surface boundary of the field oxide layer 214 and an active region.

According to the second embodiment of the present invention, after selectively (and partially) etching the oxide layer pattern 202 to cause the first silicon layer pattern 204 and the substrate 200 to protrude, the first silicon layer pattern 204 and the substrate 200 are selectively etched. By doing so, the bottom edge portion of the first silicon layer pattern 204 and the upper edge portion of the substrate 200, (which both protrude as compared with the oxide layer pattern 202), are rounded. If the oxidation of the inner surface portion of the trench is carried out at this state, each sidewall of the first silicon layer pattern 204 advantageously has a negative slope.

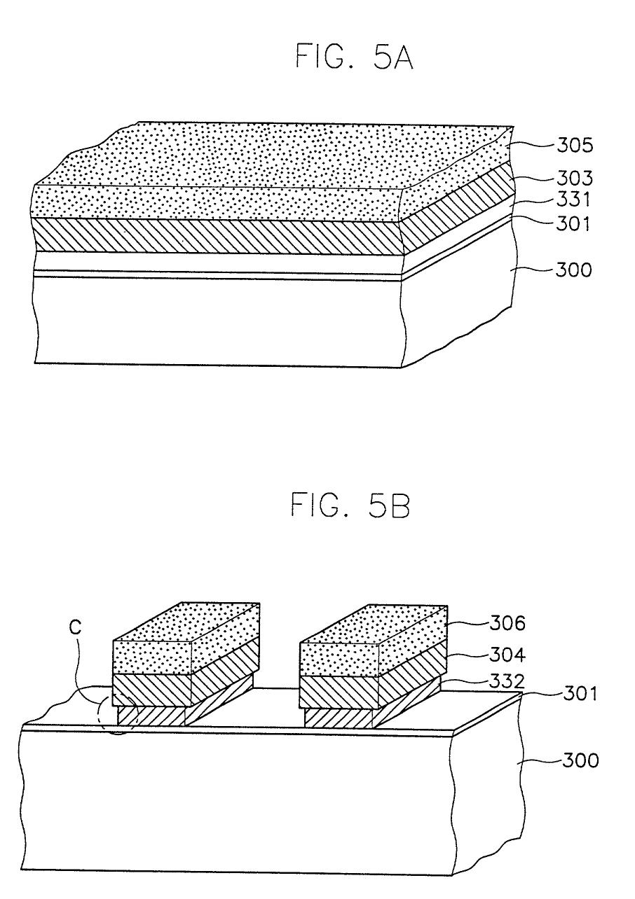

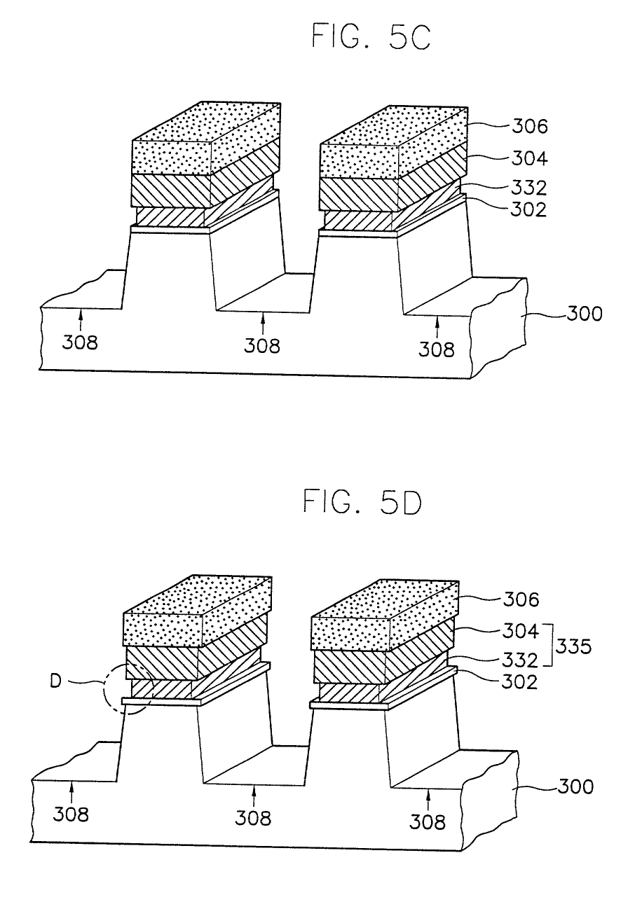

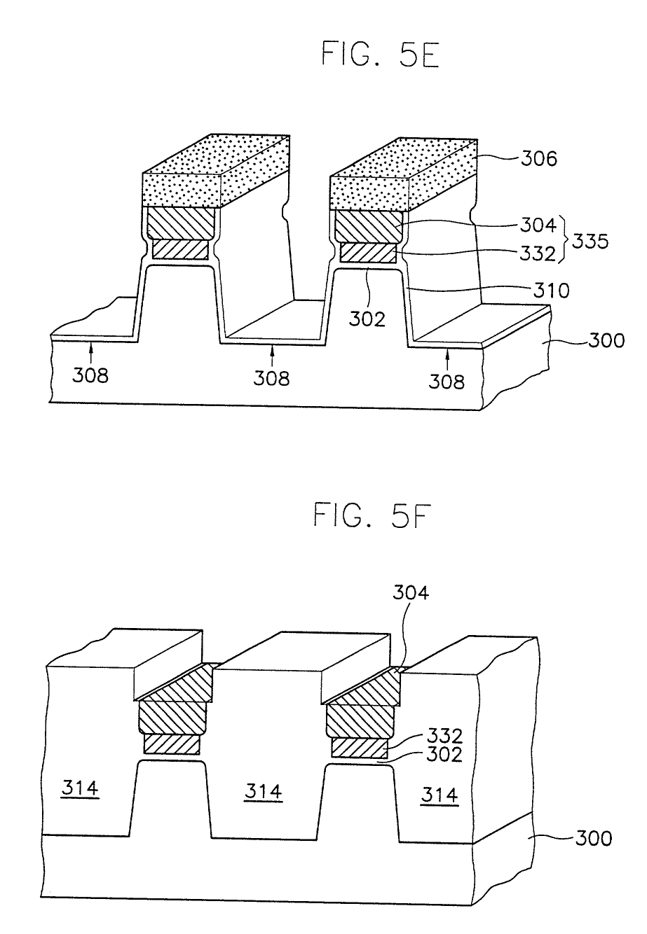

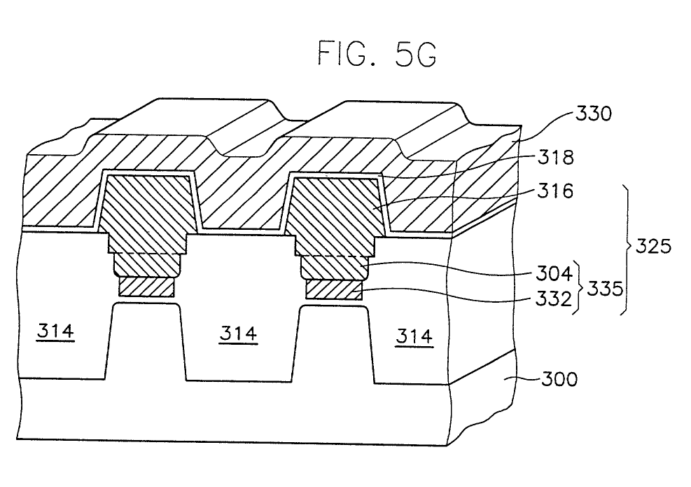

FIGS. 5A to 5G are perspective views illustrating a method of manufacturing a non-volatile memory device using the self-aligned shallow trench isolation process according to the third embodiment of the present invention.

Referring to FIG. 5A, a silicon oxide layer or silicon oxynitride layer having a thickness of preferably below about 100 Å is grown on a semiconductor substrate 300 to form an oxide layer 301 which is to be used as a gate oxide layer (e.g., tunnel oxide layer) of a cell transistor. The substrate 300 is preferably comprised of, for example, a material such as a silicon. By using SiH₄ gas and GeH₄ gas as reaction gases, a germanium (Ge)-doped silicon layer 331 is deposited via an in-situ doping method so that a doping concentration of Ge is about 0.1 atomic percent to about 0.3 atomic percent. It is preferable that the thickness of the Ge-doped silicon layer 331 is less than about half of the thickness of a first silicon layer formed in a subsequent step thereon, for example, about 150 Å to about 500 Å. More particularly, the Ge-doped silicon layer 331 is preferably deposited so that the doping concentration of Ge is highest at the initial stage of deposition and gradually decreases as the deposition progresses. In the present embodiment for example, the doping concentration of Ge is about 0.1 atomic percent to about 0.3 atomic percent at the initial stage of deposition; after the deposition is completed, the doping concentration of Ge in the surface of the Ge-doped silicon layer 331 is removed or almost 0 atomic percent. The reason why the thin film is deposited so as to vary the doping concentration therein will be described in further detail below.

Next, a first silicon layer 303 which is to be used a floating gate is deposited on the Ge-doped silicon layer 331 to a thickness of preferably about 300 Å to about 1000 Å, via a LPCVD method. Then, the first silicon layer 303 is doped with a high-concentration of N-type impurities via a typical doping method, for example, POCl₃ diffusion, ion implantation or in-situ doping, etc. The Ge-doped silicon layer 331 and the first silicon layer 303 both serve as the floating gate.

Subsequently, a nitride layer 305 is deposited on the first silicon layer 303 to a thickness of preferably about 1000 Å to about 2000 Å, via a LPCVD method.

Referring to FIGS. 5A and 5B, the nitride layer 305, the first silicon layer 303 and the Ge-doped silicon layer 331 are dry etched to form a nitride layer pattern 306, a first silicon layer pattern 304 and a Ge-doped silicon layer pattern 332 via a photolithography process using one mask for defining a floating gate. In the present embodiment for example, since the dry etch rate of the Ge-doped silicon layer 331 is higher than that of the first silicon layer 303 (as shown in the following Table 1), an undercut C is formed in the Ge-doped silicon layer 331 to cause the first silicon layer pattern 304 to protrude as compared with the Ge-doped silicon layer pattern 332.

TABLE 1

| | Silicon layer | Ge-doped silicon layer |
|---|---|---|
| When applying | 23 to 35 Å/sec | ˜65 Å/sec |
| conventional silicon | | |
| etching recipe | | |

Referring to FIGS. 5B and 5 C, by using the above mask discussed in FIG. 5B, the oxide layer 301 is dry etched to form an oxide layer pattern 302. Next, the exposed upper portion of the substrate 300 is etched away to a depth of about 2000 Å to about 5000 Å, thereby forming trenches 308. As a result, the first silicon layer patterns 304 and the Ge-doped silicon layer patterns 332 are separated from one another by the trench 308. By forming the trench 308, the active region and the floating gate are simultaneously defined using a single mask. Accordingly, the floating gate is self-aligned with the active region.

Referring to FIG. 5D, a conventional cleaning process for curing silicon damages caused by the trench etching process is performed. This cleaning process is performed using, for example, a standard cleaning-1 (SC-1). The SC-1 is a liquid composition including NH₄OH, H₂O₂ and H₂O. During the above cleaning process, the silicon layer and silicon substrate are consumed to some degree. Thus, as shown in D of FIG. 5D, the undercut of the Ge-doped silicon layer pattern 332 is caused to become enlarged. This is because the wet etch rate of the Ge-doped silicon layer pattern 332 is higher than that of the first silicon layer pattern 304 as shown in the following Table 2.

TABLE 2

| | Silicon layer | Ge-doped silicon layer |
|---|---|---|
| Cleaning condition: | ˜30 Å | 90 to 95 Å |
| SC-1, 10 minutes | | |

As shown in Table 1 and Table 2, if the silicon layer is doped with Ge, the dry etch rate and wet etch rate thereof are greater than those of a typical silicon layer. Further, as the doping concentration of Ge increases, the etch rate thereof becomes greater. Accordingly, if the deposition of the Ge-doped silicon layer progresses while the doping concentration of Ge is gradually decreased, the lower portion of the Ge-doped silicon layer pattern 332 is undercut more than the upper portion thereof. As a result, each sidewall of a silicon stack 335 (comprising the first silicon layer pattern 304 and the Ge-doped silicon layer pattern 332) has a negative slope.

Referring to FIG. 5E, the inner surface portion of the trench 308 is treated in the oxidation atmosphere to eliminate silicon damage caused by high-energy ion impact during the trench etching process and to prevent current leakage. Then, a trench thermal oxide layer 310 is formed along the inner surface of the trench 308, i.e., the bottom surface and sidewalls thereof, to the thickness of preferably about 20 Å to about 500 Å. To minimize the stress during the formation of the oxide layer, the trench thermal oxide layer 310 is preferably formed at a temperature of more than 700° C., via a wet oxidation method.

According to the present embodiment, the oxide layer pattern 302 protrudes as compared with the Ge-doped silicon layer pattern 332, and each sidewall of a silicon stack 335 (which comprises the first silicon layer pattern 304 and the Ge-doped silicon layer pattern 332), has a negative slope. Subsequently, the oxidation of the inner surface portion of the trench is performed at this state. By doing so, at the edge portion of the interface between the Ge-doped silicon layer pattern 332 and the oxide layer pattern 302, the volume expansion due to the oxidation progresses along the lateral surface of the protruding oxide layer pattern 302. As a result, the negative slope of each sidewall of the silicon stack 335 is maintained.

Referring to FIG. 5F, an oxide layer with good gap-filling characteristics, e.g., USG, O₃-TEOS USG, or a high-density plasma (HDP) oxide layer, is deposited via a CVD method to a thickness of preferably about 5000 A in order to fill the trenches 308. Then, the CVD-oxide layer is removed via an etch-back or CMP process until an upper surface of nitride layer pattern 306 of FIG. 5E is exposed, thereby forming a field oxide layer 314 inside the trench 308.

Thereafter, the nitride layer pattern 306 is removed via a stripping process using phosphoric acid to expose the first silicon layer pattern 304, and a pre-cleaning step is then performed to clean the substrate by using an etchant including fluoride acid.

Referring to FIG. 5G, a second silicon layer for the floating gate is deposited on the first silicon layer pattern 304 and the field oxide layer 314 via a LPCVD method to a thickness of preferably over about 3000 Å. Subsequently, the second silicon layer is doped with a high concentration of N-type impurity via a typical doping method. Then, the second silicon layer on the field oxide layer 314 is partially removed via a photolithography process to form a second silicon layer pattern 316.

Next, after forming an ONO dielectric interlayer 318 on the entire surface of the resultant structure, a control gate 330 which is obtained by stacking an N⁺ type-doped polysilicon layer and a metal silicide layer such as tungsten silicide (WSix), titanium silicide (TiSix), cobalt silicide (CoSix), and tantalum silicide (TaSix), is formed on the dielectric interlayer 318. Preferably, the polysilicon layer of the control gate 330 is formed to a thickness of about 1000 Å and the metal silicide layer thereof is formed to a thickness of about 1000 Å to about 1500 Å.

After patterning the control gate 330 via a photolithography process, the exposed dielectric interlayer 318, the second silicon layer pattern 316, the first silicon layer pattern 304 and the Ge-doped silicon layer pattern 332 are preferably successively patterned in each cell unit via a dry etch method. As a result, a stacked gate comprising the floating gate 325 (which comprises the Ge-doped silicon layer 332 and the first and second silicon layer patterns 304 and 316), and the control gate 330 is formed on the memory cell region.

Because each sidewall of the silicon stack 335 comprising the first silicon layer pattern 304 and the Ge-doped silicon layer pattern 332 has a negative slope, the exposed portions of the silicon stack 335 are completely removed during the above-described dry etch process. Therefore, silicon residue does not remain on the surface boundary of the field oxide layer 314 and the active region.

According to the third embodiment of the present invention, the Ge-doped silicon layer 331 having higher dry etch rates and higher wet etch rates than those of a typical silicon layer, is interposed between the oxide layer 301 and the first silicon layer 303 (refer to FIG. 5A). By doing so, each sidewall of the silicon stack 335 has a negative slope. Further, since the oxide layer pattern protrudes without an additional etching process, each sidewall of the silicon stack 335 maintains the negative slope after the inner surface portion of the trench is oxidized.

As described above, according to the first embodiment of the present invention, the first silicon layer pattern aligned to the trench and the substrate are selectively etched to protrude the oxide layer pattern, and then the inner surface of the trench is oxidized. At the edge portion of the interface between the first silicon layer pattern and oxide layer pattern, the volume expansion due to oxidation progresses laterally along the surface of the protrusive oxide layer pattern. Thus, the positive slope of the sidewall of the first silicon layer can be avoided.

According to the second embodiment of the present invention, after selectively etching the oxide layer pattern to protrude the first silicon layer pattern and substrate, the first silicon layer pattern and substrate are selectively etched or, alternatively, a hydrogen (H₂) annealing process is carried out. As a result, the bottom edge portion of the first silicon layer pattern and the upper edge portion of the substrate, which both protrude as compared with the oxide layer pattern, are rounded. If the oxidation of the inner surface portion of the trench is carried out at this state, each sidewall of the first silicon layer pattern has a negative slope.

According to the third embodiment of the present invention, the Ge-doped silicon layer having higher dry etch rate and wet etch rates than those of a typical silicon layer is inserted between the oxide layer and first silicon layer. By doing so, each sidewall of the silicon stack which comprises the first silicon layer pattern and the Ge-doped silicon layer pattern, has a negative slope. Further, since the oxide layer pattern protrudes without an additional etching process, each sidewall of the silicon stack maintains the negative slope after the inner surface of the trench is oxidized.

Therefore, according to the above-described embodiments of the present invention, the exposed portions of the silicon layer pattern or the silicon stack are completely removed during a subsequent dry etching process for forming gates. Thus, the silicon residue does not remain at the surface boundary of the field oxide layer and the active region. Advantageously, the absence of this residue helps avoid electrical failures of the device caused by short-circuiting among the neighboring gates.

Although illustrative embodiments of the present invention have been described herein with reference to the accompanying drawings, it is to be understood that the present invention is not limited to those precise embodiments, and that various other changes and modifications may be affected therein by one skilled in the art without departing from the scope or spirit of the present invention. All such changes and modifications are intended to be included within the scope of the invention as defined by the appended claims.

What is claimed is:

1. A method for self-aligned shallow trench isolation comprising the steps of:
forming an oxide layer on a semiconductor substrate;
forming a first silicon layer on the oxide layer;
forming a nitride layer on the first silicon layer;
etching the nitride layer, the first silicon layer and the oxide layer using a single mask to thereby form an oxide layer pattern, a first silicon layer pattern and a nitride layer pattern;
etching an upper portion of the substrate adjacent to the first silicon layer pattern using the mask to thereby form a trench;
selectively etching the first silicon layer pattern and the substrate to protrude the oxide layer pattern as compared with the first silicon layer pattern and the substrate;
oxidizing an inner surface portion of the trench to form a trench thermal oxide layer on an inner surface of the trench; and
forming a field oxide layer for filling up the trench.

2. The method as claimed in claim 1, wherein a thickness selectively etched from the first silicon layer pattern and the substrate is more than about 50% of a thickness of an oxidized quantity of the inner surface of the trench.

3. The method as claimed in claim 2, wherein an amount selectively etched from the first silicon layer pattern and the substrate is more than about 30 Å.

4. The method as claimed in claim 1, wherein the step of selectively etching the first silicon layer pattern and the substrate is performed using an isotropic etch method.

5. The method as claimed in claim 1, wherein the step of oxidizing the inner surface of the trench is performed at a temperature of over about 700° C. via a wet oxidation method.

6. The method as claimed in claim 1, wherein the field oxide layer is formed by forming a chemical vapor deposition (CVD)-oxide layer covering the nitride layer pattern while filling up the trench, and etching the CVD-oxide layer to have a smooth surface via one of a chemical mechanical polishing (CMP) method and an etch-back method until the surface of the nitride layer pattern is exposed.

7. A method for self-aligned shallow trench isolation comprising the steps of:
forming an oxide layer on a semiconductor substrate;
forming a first silicon layer on the oxide layer;
forming a nitride layer on the first silicon layer;
etching the nitride layer, the first silicon layer and the oxide layer using a single mask to thereby form an oxide layer pattern, a first silicon layer pattern and a nitride layer pattern;
etching an upper portion of the substrate adjacent to the first silicon layer pattern using the mask to thereby form a trench;
selectively etching the oxide layer pattern to protrude the first silicon layer pattern and the substrate as compared with the oxide layer pattern;
rounding a bottom edge portion of the first silicon layer pattern and an upper edge portion of the substrate;
oxidizing an inner surface portion of the trench to form a trench thermal oxide layer on an inner surface of the trench; and
forming a field oxide layer for filling up the trench.

8. The method as claimed in claim 7, wherein an amount selectively etched from the oxide layer pattern is more than about 100 Å.

9. The method as claimed in claim 7, wherein the step of selectively etching the oxide layer pattern is performed using an isotropic etch method.

10. The method as claimed in claim 7, wherein the step of rounding a bottom edge portion of the first silicon layer pattern and an upper edge portion of the substrate is performed by selectively etching the first silicon layer pattern and the substrate.

11. The method as claimed in claim 10, wherein the step of selectively etching the first silicon layer pattern and the substrate is performed using an isotropic etch method.

12. The method as claimed in claim 10, wherein an amount selectively etched from the first silicon layer pattern and the substrate is less than that of the oxide layer pattern.

13. The method as claimed in claim 10, wherein a thickness selectively etched from the first silicon layer pattern and the substrate is more than about 40% of a thickness of an oxidized quantity of the inner surface of the trench.

14. The method as claimed in claim 7, wherein the step of rounding a bottom edge portion of the first silicon layer pattern and an upper portion of the substrate is performed using an H2 annealing process.

15. The method as claimed in claim 14, wherein the H₂ annealing process is performed at a temperature of about 750° C. to about 950° C.

16. A method for self-aligned shallow trench isolation comprising the steps of:
forming an oxide layer on a semiconductor substrate;
forming a Ge-doped silicon layer on the oxide layer;
forming a first silicon layer on the Ge-doped silicon layer;
forming a nitride layer on the first silicon layer;
etching the nitride layer, the first silicon layer, the Ge-doped silicon layer and the oxide layer using a single mask to thereby form an oxide layer pattern, a Ge-doped silicon layer pattern, a first silicon layer pattern and a nitride layer pattern, and simultaneously, to form an undercut in the Ge-doped silicon layer pattern;
etching an upper portion of the substrate adjacent to the first silicon layer pattern using the mask to thereby form a trench;
oxidizing an inner surface portion of the trench to form a trench thermal oxide layer on an inner surface of the trench; and
forming a field oxide layer for filling up the trench.

17. The method as claimed in claim 16, wherein the thickness of the Ge-doped silicon layer is less than about half of thickness of the silicon layer.

18. The method as claimed in claim 16, wherein the doping concentration of Ge in the Ge-doped silicon layer is about 0.1 atomic percent to about 0.3 atomic percent.

19. The method as claimed in claim 16, wherein the Ge-doped silicon layer is deposited so that the doping concentration of Ge gradually decreases as deposition progresses.

20. The method as claimed in claim 19, wherein the Ge-doped silicon layer is formed so that the doping concentration of Ge is about 0.1 atomic percent to about 0.3 atomic percent at the initial stage and the doping concentration of Ge in the surface thereof is removed after deposition is completed.

21. A method of manufacturing a non-volatile memory device comprising the steps of:
forming an oxide layer for gate oxide layer on a semiconductor substrate;
forming a first silicon layer for a floating gate on the oxide layer;
forming a nitride layer the first silicon layer;
etching the nitride layer, the first silicon layer and the oxide layer using a single mask to thereby form an oxide layer pattern, a first silicon layer pattern and a nitride pattern;
etching an upper portion of the substrate adjacent to the first silicon layer using the mask to thereby form a trench aligned with the first silicon layer pattern for defining an active region of the substrate;
selectively etching the first silicon layer pattern and the substrate to protrude the oxide layer pattern as compared with the first silicon layer pattern and the substrate;
oxidizing an inner surface portion of the trench to form a trench thermal oxide layer on an inner surface of the trench;
forming a field oxide layer for filling up the trench; and
successively forming a dielectric interlayer and a control gate on the first silicon layer pattern.

22. The method as claimed in claim 21, wherein a thickness selectively etched from the first silicon layer pattern and the substrate is more than about 50% of a thickness of an oxidized quantity of the inner surface of the trench.

23. The method as claimed in claim 22, wherein an amount selectively etched from the first silicon layer pattern and the substrate is more than about 30 Å.

24. The method as claimed in claim 21, wherein the step of selectively etching the first silicon layer pattern and the substrate is performed using an isotropic etch method.

25. The method as claimed in claim 21, wherein the step of oxidizing the inner surface of the trench is performed at a temperature of over about 700° C. via a wet oxidation method.

26. The method as claimed in claim 21, wherein the field oxide layer is formed by forming a chemical vapor deposition (CVD)-oxide layer covering the nitride layer pattern while filling up the trench, and etching the CVD-oxide layer to have a smooth surface via one of a chemical mechanical polishing (CMP) method and an etch back method until the surface of the nitride layer pattern is exposed.

27. The method as claimed in claim 21, further comprising the steps of: forming a second silicon layer for the floating gate on the first silicon layer pattern and the field oxide layer; and
removing the second silicon layer on the field oxide layer to form a second silicon layer pattern, before forming the dielectric interlayer.

28. A method of manufacturing a non-volatile memory device comprising the steps of:
forming an oxide layer for a gate oxide layer on a semiconductor substrate;
forming a first silicon layer for a floating gate on the oxide layer;
forming a nitride layer on the first silicon layer;
etching the nitride layer, the first silicon layer and the oxide layer using a single mask to thereby form an oxide layer pattern, a first silicon layer pattern and a nitride layer pattern;
etching an upper portion of the substrate adjacent to the first silicon layer pattern using the mask to thereby form a trench aligned with the first silicon layer pattern for defining an active region of the substrate;
selectively etching the oxide layer pattern to protrude the first silicon layer pattern and the substrate as compared with the oxide layer pattern;
rounding a bottom edge portion of the first silicon layer pattern and an upper edge portion of the substrate;
oxidizing an inner surface portion of the trench to form a trench thermal oxide layer on an inner surface of the trench;
forming a field oxide layer for filling up the trench; and
successively forming a dielectric interlayer and a control gate on the first silicon layer pattern.

29. The method as claimed in claim 28, wherein the step of selectively etching the oxide layer pattern is performed using an isotropic etch method.

30. The method as claimed in claim 28, wherein an amount selectively etched from the oxide layer pattern is more than about 100 Å.

31. The method as claimed in claim 28, wherein the step of selectively etching the oxide layer pattern is performed using an isotropic etching process.

32. The method as claimed in claim 28, wherein the step of rounding a bottom edge portion of the first silicon layer pattern and an upper edge portion of the substrate is performed by selectively etching the first silicon layer pattern and the substrate.

33. The method as claimed in claim 32, wherein the step of selectively etching the first silicon layer pattern and the substrate is performed using an isotropic etching process.

34. The method as claimed in claim 32, wherein an amount selectively etched from the first silicon layer pattern and the substrate is less than that of the oxide layer pattern.

35. The method as claimed in claim 32, wherein a thickness selectively etched from the first silicon layer pattern and the substrate is more than about 40% of a thickness of an oxidized quantity of the inner surface of the trench.

36. The method as claimed in claim 28, wherein the step of rounding a bottom edge portion of the first silicon layer pattern and an upper edge portion of the substrate is performed using an H₂ annealing process.

37. The method as claimed in claim 36, wherein the H2 annealing process is performed at a temperature of about 750° C. to about 950° C.

38. A method of manufacturing a non-volatile memory device comprising the steps of:
forming an oxide layer for a gate oxide layer on a semiconductor substrate;
forming a Ge-doped silicon layer for a floating gate on the oxide layer;
forming a first silicon layer for the floating gate on the Ge-doped silicon layer;
forming a nitride layer on the first silicon layer;
etching the nitride layer, the first silicon layer, the Ge-doped silicon layer and the oxide layer using a single mask to thereby form an oxide layer pattern, a Ge-doped silicon layer pattern, a first silicon layer pattern and a nitride layer pattern, and simultaneously, to form an undercut in the Ge-doped silicon layer pattern;
etching an upper portion of the substrate adjacent to the first silicon layer pattern using the mask to thereby form a trench aligned with the first silicon layer pattern for defining an active region of the substrate;
oxidizing an inner surface portion of the trench to form a trench thermal oxide layer on an inner surface of the trench;
forming a field oxide layer for filling up the trench; and
successively forming a dielectric interlayer and a control gate on the first silicon layer pattern.

39. The method as claimed in claim 38, wherein the thickness of the Ge-doped silicon layer is less than about half of thickness of the silicon layer.

40. The method as claimed in claim 38, wherein the doping concentration of Ge in the Ge-doped silicon layer is about 0.1 atomic percent to about 0.3 atomic percent.

41. The method as claimed in claim 38, wherein the Ge-doped silicon layer is deposited so that the doping concentration of Ge gradually decreases as deposition progresses.

42. The method as claimed in claim 41, wherein the Ge-doped silicon layer is formed so that the doping concentration of Ge is about 0.1 atomic percent to about 0.3 atomic percent at the initial stage, and the doping concentration of Ge in the surface thereof is removed after deposition is completed.
